(19) United States
(12) Patent Application Publication
(10) Pub. No.: US 2005/0062059 A1
(43) Pub. Date: Mar. 24, 2005

(54) Light emission diode (LED)

(76) Inventor: De-Sen Huang, Fujian (CN)

Correspondence Address: CHARLES E. BAXLEY, ESQ., 90 JOHN STREET, THIRD FLOOR, NEW YORK, NY, 10038, US

(21) Appl. No.: 10/816,985

(22) Filed: Apr. 2, 2004

(30) Foreign Application Priority Data
Sep. 22, 2003 (CN) CH 03158333.4

(51) Int. Cl. H01L 33/00

(52) U.S. Cl. 257/100

(57) ABSTRACT

A light emitting diode (LCD) comprised of a heat conduction substrate, a circuitry on the substrate, an insulation layer between the substrate and the circuit, multiple light emitting chips distributed in the space between the circuitry and the substrate, light emitting chips being connected to the circuitry through metallic conductor, and a light permeable protection layer being topped on those light emitting chips to significantly improve its power dissipation effect, lower light emission chip junction temperature, increase light emission efficacy and service life, increase the quantity of the light emission chip of unit area, and improve the light emission efficiency of unit area.

### BACKGROUND OF THE INVENTION

(a) Field of the Invention

The present invention is related to a light emitting diode (LCD).

(b) Description of the Prior Art

LED packaging technology of the prior art involves gluing light emission chips to a frame, connection of metallic conductor between chips and frame, packaged with epoxy, and finally having the LEC welded to a PCB using the plug-in package method. Whereas power dissipation of the LED of the prior art takes place at the frame, power dissipation in the form of heat is poor to cause higher junction temperature of the light-emitting chip and negatively affect the light emitting efficacy and service light of the LED. Furthermore, the number of the distribution of the light emitting chips by unit area is comparatively lesser to be applicable in the ordinary illumination that requires higher luminance. Therefore, the LED manufacturing industry has been desperately solving the problem of how to increase LED efficacy and service life by lowering the junction temperature of the light emitting chips, and the number of the number of light emitting chips of unit area so to fully utilize the advantages of longer service life and less power consumption of LED in the wider range of applications, and to make LED the environment friendly product to replace the conventional lighting source.

### SUMMARY OF THE INVENTION

The primary purpose of the present invention is to provide a light emitting diode (LED) to significantly improve the power dissipation of the LED, lower the junction temperature of the light emitting chip, increase the light emitting efficacy and service lift of the LED, and permit the number of the light emitting chip of unit area, thus to upgrade the light emitting efficiency of unit area.

To achieve the purpose, the LED is essentially comprised of heat conduction substrate, circuitry provided on the heat conduction substrate, an insulation layer disposed between the heat conduction substrate and the circuitry, multiple light emitting chips distributed among the circuitry and the space above the heat conduction substrate and connected to the circuitry through metal conductor, and a protection layer at the top of those light emitting chips.

Another purpose of the present invention is to provide a light emitting diode, wherein, a recess or a trough is formed on the heat conduction substrate and those light emitting chips are distributed at the bottom of the recess or trough while being covered up with a light permeable protection layer.

Another purpose yet of the present invention is to provide a light emitting diode, wherein, a light permeable optical lens is provided on the light emitting chip and fixed to where above the light-emitting chip.

Another purpose yet of the present invention is to provide a light emitting diode, wherein, a circuit is formed among multiple light emitting chips through a metal conductor and both ends of the circuit is then connected to the circuitry on the substrate.

Another purpose yet of the present invention is to provide a light emitting diode, wherein, the LED is made into a module and multiple modules are distributed on a support board while a circuit or a conductor is used for connection among the modules, and the modules are locked to the support board.

Another purpose yet of the present invention is to provide a light emitting diode, wherein; the heat conduction substrate is made into a bow shape with light emitting chips and circuitry distributed thereon.

Another purpose yet of the present invention is to provide a light emitting diode, wherein; a fan is adapted to the heat conduction substrate.

Those light emitting chips are distributed among the circuitry and in the space above the insulation layer, or glued among the circuitry and in the space above the heat conduction substrate or the insulation layer.

Whereas the heat conduction substrate is provided, those light emitting chips are capable of fast dissipating the heat through the heat conduction substrate to lower their junction temperature, thus to increase efficacy and service life of the light emitting chip, and to realize the lay up of more light emitting chips on the unit area. The recess or the trough provided on the heat conduction substrate help converge the light and various circuitries can be arranged among the light emitting chips and/or between light emitting chips and the circuitry depending on the individual application. Furthermore, the light emitting chip can be made into various types of modules for mass production by lot and mounted on the support board depending on the individual application to form a lighting source or light emitting source.

### BRIEF DESCRIPTION OF THE DRAWINGS

FIG. 1 is a bird's view of a first preferred embodiment of the present invention.

FIG. 2 is a blowup sectional view showing a local part of the first preferred embodiment of the present invention.

FIG. 3 is a blowup sectional view showing a local part of a second preferred embodiment of the present invention.

FIG. 4 is a perspective view of a third preferred embodiment of the present invention.

FIG. 5 is a bird's view of a fourth preferred embodiment of the present invention.

FIG. 6 is a bird's view of a fifth preferred embodiment of the present invention.

FIG. 7 is a bird's view of a sixth preferred embodiment of the present invention.

FIG. 8 is a sectional view taken from section A-A of the sixth preferred embodiment of the present invention.

FIG. 9 is a bird's view of a seventh preferred embodiment of the present invention.

FIG. 10 is a blowup sectional view showing a local part of the seventh preferred embodiment of the present invention.

FIG. 11 is a side view of an eighth preferred embodiment of the present invention.

FIG. 12 is a sectional view of a ninth preferred embodiment of the present invention.

### DETAILED DESCRIPTION OF THE PREFERRED EMBODIMENTS

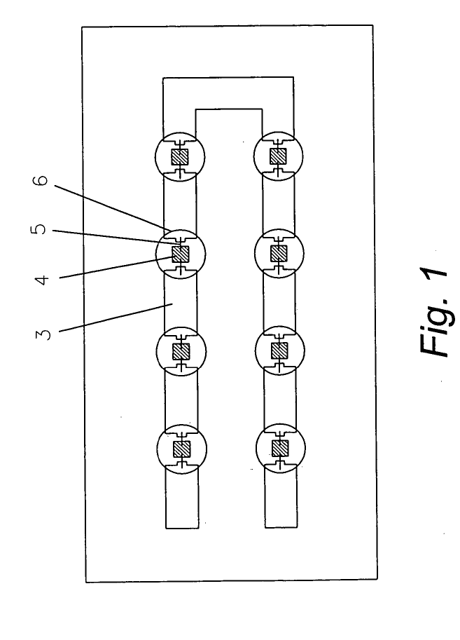

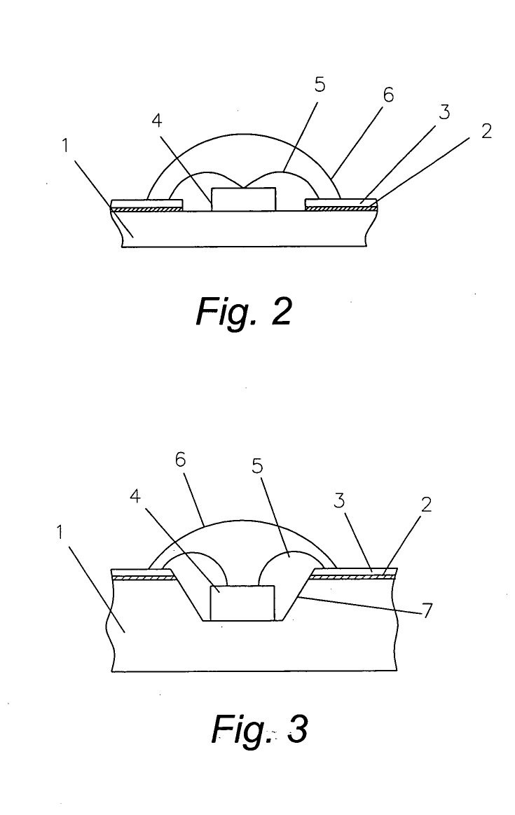

Referring to FIGS. 1 and 2, a LED of the present invention includes a heat conduction substrate 1; a circuitry 3 is provided on the heat conduction substrate 1; an insulation layer 2 is provided between the heat conduction substrate 1 and the circuitry 3; multiple light emitting chips 4 are arranged among the circuit in the space over the heat conduction substrate; those light emitting chips 4 are each connected to the circuitry 3 by means of a metal conductor 5; and those light emitting chips 4 are covered up with a light permeable protection layer 6.

The heat conduction substrate 1 is made of ceramic material provided with good aluminum and copper heat conduction property or any other material with good heat conduction property. The insulation layer 2 yields powerful insulation property, and the circuitry 3 on the top of the insulation layer 2 may be related to a copper foil to be etched with various circuits as required.

Those light emitting chips 4 are arranged among the circuit and in the space over the heat conduction substrate 1, or among the copper foil and on the insulation layer 2 above the heat conduction substrate 1. Furthermore, those light emitting chips 4 are glued among the circuitry 3 and in the space over the heat conduction substrate 1 or the insulation layer 2. The light emitting chip 4 is each connected to the circuitry 3 with a metal conductor 5 and is covered up with the light permeable protection layer 6. The protection layer 6 is made of epoxy or silicon rubber in an arc form for light convergence and light color conversion. For example, when fluorescent powder is added into the protection layers, the blue light emitted from the light emitting chip 4 is converted into while light.

Whereas harder heat conduction materials with stronger heat conduction property, the light emitting chip 4 for being firmly glued to the heat conduction substrate 1 rapidly dissipate the heat to significantly decrease the junction temperature, thus to increase its light emitting efficiency and service lift while realizing the purpose of having more light emitting chips 4 in smaller unit area. Furthermore, the heat conduction substrate 1 functions as a support for the LED.

As illustrated in FIG. 3, an arc recess 7 is formed on the heat conduction substrate 1 and those light emitting chips 4 are distributed at the bottom of the arc recess 7, and connected to the circuitry 3 with a metal conductor 5 a light permeable protection layer 6 covers up the light emitting chip 4 and the arc recess 7. The arc recess 7 reflects the light emitted from the light emitting chip 4 and refract the light towards a direction away from the substrate 1 to increase light emitting efficiency and enlarge the contact area with the heat conduction substrate 1 for further enhancing heat conduction result between the light emitting chip 4 and the heat conduction substrate 1.

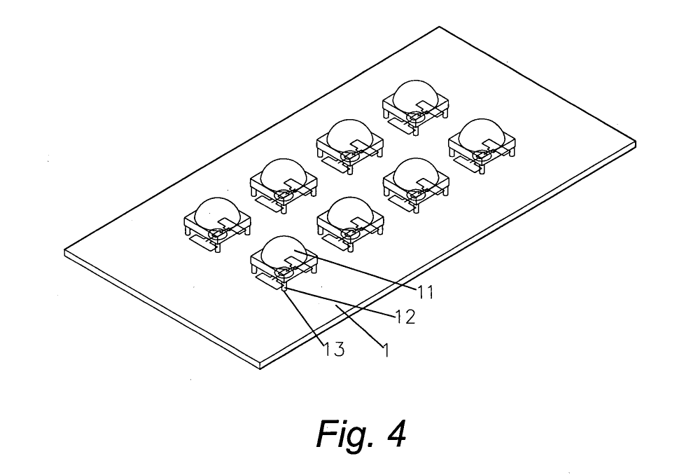

A third preferred embodiment of the present invention as illustrated in FIG. 4 is provided with a light permeable optical lens 11 with four footages 12 on the light emitting chip 4. Four respective holes 13 are respectively provided on the peripheral of the light emitting chip 4 on the heat conduction substrate 1 to fix the optical lens 11 above the light emitting chip 4. Accordingly, the light from the light emitting chip 4 is transmitted through the optical lens 11. Alternatively, the optical lens 11 is forthwith adhered to the heat conduction substrate 1.

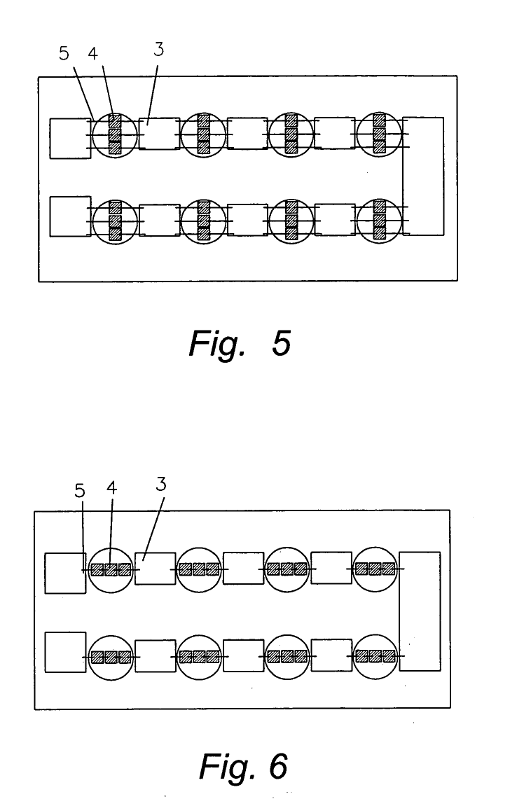

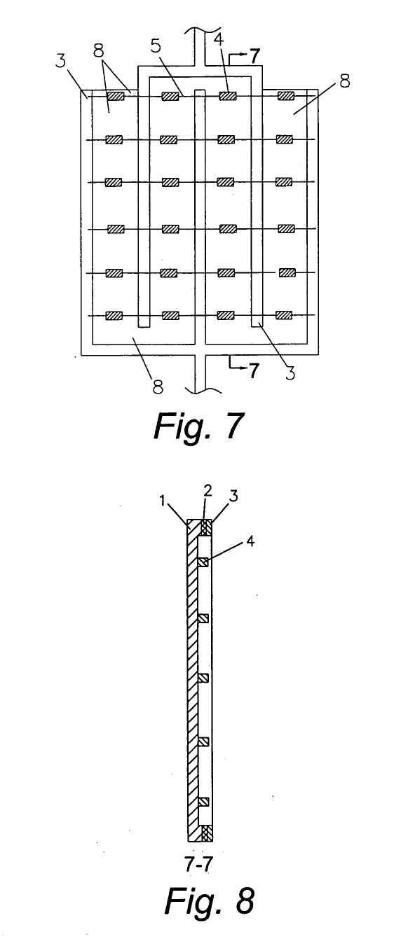

A fourth preferred embodiment of the present invention as illustrated in FIG. 5, three light emitting chips 4 are at the same time distributed on the bottom of the recess 7 and are respectively connected to the circuitry 3 with the metal conductor 5. As illustrated in FIG. 6, three light emitting chips 4 are connected in series through the metal conductor 5 in a fifth preferred embodiment of the present invention, and then both ends of the series circuit is connected to the circuitry 3. FIGS. 7 and 8 show a sixth preferred embodiment of the present invention, wherein, a trough 8 is formed on the heat conduction substrate among the circuitry 3 with each of those light emitting chip 4 connected to the circuitry 3 through the metal conductor 5. Alternatively, a series circuit is formed first with metal conductor among those light emitting chips 4 and having both ends of the series circuit to be connected to the circuitry 3. Depending on the individual application, various circuit structures are formed between those light emitting chips 4 and the circuitry 3 for those light emitting chips 4 to be directly connected to the circuitry 3, or a parallel or a series circuit is formed first among those light emitting chips 4 before being connected to the circuitry 3 on the heat conduction substrate 1.

As described above, the light emitting chip 4 is capable of rapidly dissipating the heat. Given with the premises that each light emitting chip 4 is provided with the same light emitting efficiency and service lift, number of the light emitting chip 4 on the unit area can be increased to improve the light emitting strength of the unit area.

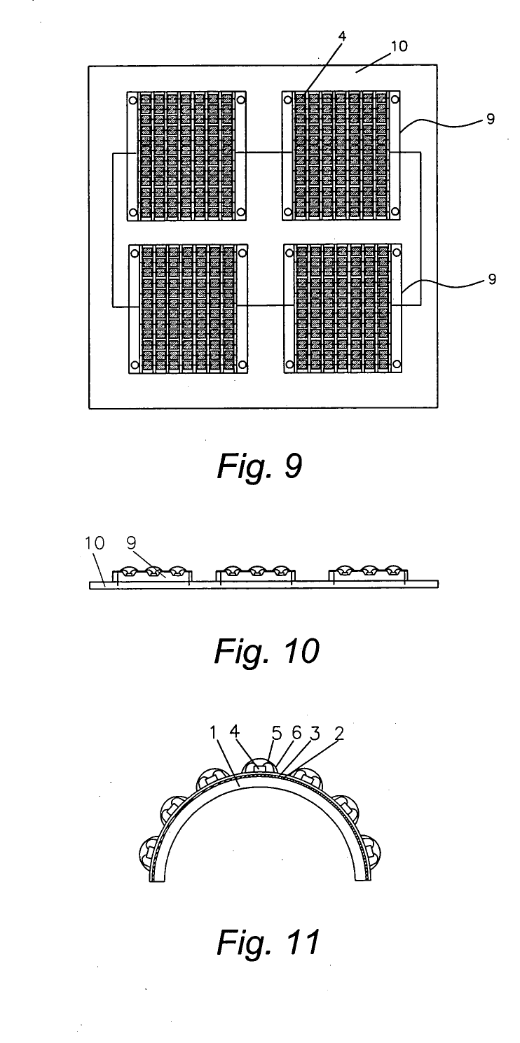

FIGS. 9 and 10 illustrated a seventh preferred embodiment of the present invention. Wherein, multiple LEDs of the present invention are made into modules 9 and distributed on a support board 10 while circuitry or metal conductor is used to connect among those modules, and those modules 9 are riveted or glued to the support board 10. Accordingly, the LED module can be realized with mass production by lot to be distributed on the support board in various forms and areas depending on the individual application. The support board 10 is made of a material of good heat conduction property to help fast dissipate the heat from the heat conduction substrate 1.

In an eighth preferred embodiment of the present invention as illustrated in FIG. 11, the heat conduction substrate 1 is made into a bow shape with those light emitting chips 4 and the circuitry distributed thereon; or alternatively, the heat conduction substrate 1 can be made into various surfaces depending on the individual application.

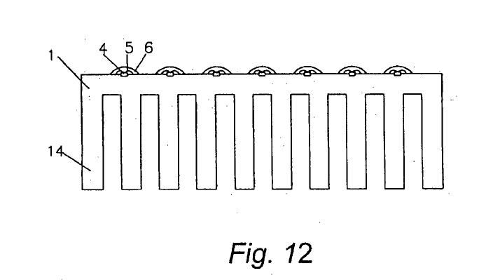

The heat conduction substrate 1 is intergraded with a power dissipation member 14 as illustrated in FIG. 12 for a ninth preferred embodiment of the present invention. Wherein, the power dissipation member 14 can be made into a stick, a sheet or in any other form that facilitates power dissipation.

Furthermore, a fan is provided on the heat conduction substrate 1 to lower its temperature and thus reduces the size of the heat conduction substrate 1 while improving the light emitting efficiency and service life of the light emitting chip 4.

1. A light emitting diode includes a heat conduction substrate, a circuitry on the heat conduction substrate, an insulation layer between the heat conduction substrate and the circuitry, multiple light emitting chips distributed among the circuitry and in the space above the heat conduction substrate and connected to the circuitry through a metal conductor, and a light permeable protection layer covering up the light emitting chips.

2. A light emitting diode as claimed in claim 1, wherein, a recess or a trough is formed on the heat conduction substrate, multiple light emitting chips are distributed at the bottom of the recess or the trough; and a light permeable protection layer covers up those light emitting chips and the recess or the trough.

3. A light emitting diode as claimed in claim 2, wherein, a recess or a trough is formed on the heat conduction substrate, multiple light emitting chips are distributed at the bottom of the recess or the trough covered up with a light permeable protection layer.

4. A light emitting diode as claimed in claim 1, wherein, those light emitting chips are distributed among the circuitry and in the space above the insulation layer.

5. A light emitting diode as claimed in claim 2, wherein, those light emitting chips are glued among the circuitry and in the space above the heat conduction substrate or the insulation layer.

6. A light emitting diode as claimed in claim 1, wherein, a light permeable optical lens is provided on the light-emitting chip fixed above the light emitting chip.

7. A light emitting diode as claimed in claim 1, wherein, a circuit is formed first among multiple light emitting chips and both ends of the circuit are then connected to the circuitry on the substrate.

8. A light emitting diode as claimed in claim 1, wherein, the LED is made into a module, multiple modules are distributed on a support board, a circuit or a conductor is used for connection among those multiple modules locked to the support board.

9. A light emitting diode as claimed in claim 1, wherein, the heat conduction substrate is made in a bow shape with those light emitting chips and the circuitry distributed thereon.

10. A light emitting diode as claimed in claim 1, wherein, a fan is adapted to the heat conduction substrate.

11. A light emitting diode as claimed in claim 2, wherein, one or more than one recess or trough is provided among the circuitry and above the heat conduction substrate and multiple light emitting chips at the bottom of the recess or trough are connected to one another with a circuit.

12. A light emitting diode as claimed in claim 1, wherein, The heat conduction substrate 1 is intergraded with a power dissipation member.

13. A light emitting diode as claimed in claim 12, wherein, the power dissipation member is made into a stick, a sheet or in any other form that facilitates power dissipation.
